(19) United States
(12) Patent Application Publication
(10) Pub. No.: US 2025/0232973 A1
(43) Pub. Date: Jul. 17, 2025

(54) SUBSTRATE PROCESSING METHOD AND SUBSTRATE PROCESSING APPARATUS

(71) Applicant: SCREEN Holdings Co., Ltd., Kyoto (JP)

(72) Inventors: Tetsuya EMOTO, Kyoto (JP); Hidekazu ISHIKAWA, Kyoto (JP); Tomonori KOJIMARU, Kyoto (JP); Pohling THEN, Kyoto (JP)

(21) Appl. No.: 19/019,865

(22) Filed: Jan. 14, 2025

(30) Foreign Application Priority Data
Jan. 15, 2024 (JP) 2024-004005

(51) Int. Cl. H01L 21/02; B08B 3/08; B08B 3/10; H01L 21/67

(52) U.S. Cl. CPC H01L 21/02057; B08B 3/08; B08B 3/10; H01L 21/67034

(57) ABSTRACT

A substrate processing method includes a liquid film forming step, a hole forming step of discharging gas at a hole-forming flow rate from a central discharge port of a fluid nozzle located at a central lower position toward a central portion of the upper surface of the substrate to form at a central portion of the liquid film an exposing hole where the central portion of the upper surface of the substrate is exposed, and a hole widening step of discharging gas at a hole-widening flow rate greater than the hole-forming flow rate, from the central discharge port of the fluid nozzle located at a central upper position higher than the central lower position, toward the central portion of the upper surface of the substrate to widen an outer edge of the exposing hole up to an outer perimeter of the upper surface of the substrate.

### BACKGROUND OF THE INVENTION

### 1. Field of the Invention

The present invention relates to a substrate processing apparatus and a substrate processing method that process substrates. The substrates include a semiconductor wafer, a substrate for a FPD (flat panel display) such as a liquid crystal display and an organic EL (electroluminescence) display, a substrate for an optical disc, a substrate for a magnetic disc, a substrate for a magneto-optical disc, a substrate for a photomask, a ceramic substrate, a substrate for a solar cell and the like, for example.

### 2. Description of Related Art

JP 2016-162847 A discloses discharging inert gas from a first moving nozzle toward the upper surface of a substrate to open a hole at the center of a liquid film of an organic solvent, and widening the hole. FIG. 9 in JP 2016-162847 A shows the first moving nozzle located at the central lower position both while opening and while widening the hole.

Gas discharged from a nozzle toward the upper surface of a substrate collides with the upper surface of the substrate and then flows along the upper surface of the substrate. However, when the nozzle discharges gas at a high flow rate while the nozzle remains near the substrate, the airflow other than the airflow that is parallel or substantially parallel to the upper surface of the substrate increases in volume or becomes stronger.

Gas discharged from the nozzle located above the substrate, on the other hand, forms a columnar or linear airflow running from the nozzle onto the upper surface of the substrate. The diameter of the airflow increases as it retreats from the nozzle. When an airflow with a large diameter collides with a liquid film on a substrate while a hole is being formed in the liquid film, the liquid tends to remain in the hole. When the nozzle is moved away from the substrate in order to reduce or weaken disturbance of the airflow, the liquid is likely to remain in the hole after the hole has been formed.

It is one of objects of the present invention to provide a substrate processing method and substrate processing apparatus that can lower the possibility of liquid remaining in the hole formed in the liquid film covering the upper surface of the substrate, and that can reduce or weaken disturbance of airflow produced when the hole is widened.

### SUMMARY OF THE INVENTION

A preferred embodiment of the present invention provides a substrate processing method including discharging processing liquid toward an upper surface of a substrate held horizontally to cover an entire upper surface of the substrate with a liquid film which is a film of the processing liquid, discharging gas at a hole-forming flow rate from a central discharge port of a fluid nozzle located at a central lower position which is a position above the substrate, toward a central portion of the upper surface of the substrate to form at a central portion of the liquid film an exposing hole where the central portion of the upper surface of the substrate is exposed, and discharging gas at a hole-widening flow rate which is greater than the hole-forming flow rate, from the central discharge port of the fluid nozzle located at a central upper position which is a position higher than the central lower position, toward the central portion of the upper surface of the substrate to widen an outer edge of the exposing hole up to an outer perimeter of the upper surface of the substrate.

In the preferred embodiment, at least one of the following features may be added to the substrate processing method.

Discharging the gas at the hole-widening flow rate includes increasing the flow rate of the gas discharged from the central discharge port up to the hole-widening flow rate when the fluid nozzle is located at the central upper position.

Discharging the gas at the hole-widening flow rate also includes increasing the flow rate of the gas discharged from the central discharge port up to the hole-widening flow rate while increasing the increase in the flow rate of gas per unit time as time passes when the fluid nozzle is located at the central upper position.

The substrate processing method further includes covering the upper surface of the substrate with gas that has been discharged in a radial manner from an annular discharge port surrounding a vertical line passing through the central portion of the upper surface of the substrate, after the exposing hole has been formed.

The substrate processing method further includes rotating the substrate around a vertical rotational axis passing through the central portion of the upper surface of the substrate while causing the central discharge port to discharge gas toward the central portion of the upper surface of the substrate at a drying flow rate which is higher than the hole-forming flow rate and lower than the hole-widening flow rate, after the outer edge of the exposing hole has been widened up to the outer perimeter of the upper surface of the substrate.

The substrate processing method further includes covering the upper surface of the substrate with gas that has been discharged at a flow rate in a radial manner from an annular discharge port surrounding a vertical line passing through the central portion of the upper surface of the substrate, while rotating the substrate around the vertical rotational axis and causing the central discharge port to discharge the gas toward the central portion of the upper surface of the substrate at the drying flow rate after the outer edge of the exposing hole has been widened up to the outer perimeter of the upper surface of the substrate, and the drying flow rate is lower than the flow rate.

The substrate processing method further includes forming between the liquid film and the upper surface of the substrate a vapor layer of the processing liquid that raises the liquid film from the upper surface of the substrate by heating the substrate before the exposing hole is formed.

Another preferred embodiment of the present invention provides a substrate processing apparatus including a substrate holder that discharges processing liquid toward an upper surface of the substrate held by the substrate holder to cover an entire upper surface of the substrate with a liquid film which is a film of the processing liquid, a fluid nozzle that discharges gas at a hole-forming flow rate from a central discharge port toward a central portion of the upper surface of the substrate held by the substrate holder, while being located at a central lower position which is a position above the substrate to form at a central portion of the liquid film an exposing hole where the central portion of the upper surface of the substrate is exposed, a nozzle actuator that lifts the fluid nozzle from the central lower position to a central upper position, and a flow rate adjustment valve that changes a flow rate of gas discharged from the central discharge port of the fluid nozzle to cause the central discharge port to discharge gas toward the central portion of the upper surface of the substrate held by the substrate holder at a hole-widening flow rate which is greater than the hole-forming flow rate and to widen an outer edge of the exposing hole up to an outer perimeter of the upper surface of the substrate when the fluid nozzle is located at the central upper position. At least one of the above-described features regarding the substrate processing method may be added to the substrate processing apparatus.

### BRIEF DESCRIPTION OF THE DRAWINGS

FIG. 1A is a schematic plan view showing a layout of a substrate processing apparatus according to a preferred embodiment of the present invention.

FIG. 1B is a schematic side view of the substrate processing apparatus.

FIG. 2 is a schematic view of an interior of a processing unit provided in the substrate processing apparatus when viewed horizontally.

FIG. 3 is a schematic view showing a vertical cross-section of a fluid nozzle provided in the processing unit.

FIG. 4 is a process chart for describing an example of processing of a substrate performed by the substrate processing apparatus.

FIG. 5A, FIG. 5B, FIG. 5C, FIG. 5D, FIG. 5E and FIG. 5F are schematic cross-sectional views showing states of the substrate when the example of processing shown in FIG. 4 is being performed.

FIG. 6 is a time chart describing an example of processing from formation of an exposing hole in a liquid film up to drying of the substrate.

### DETAILED DESCRIPTION OF PREFERRED EMBODIMENTS

Preferred embodiments of the present invention will be explained in detail with reference to the accompanying drawings.

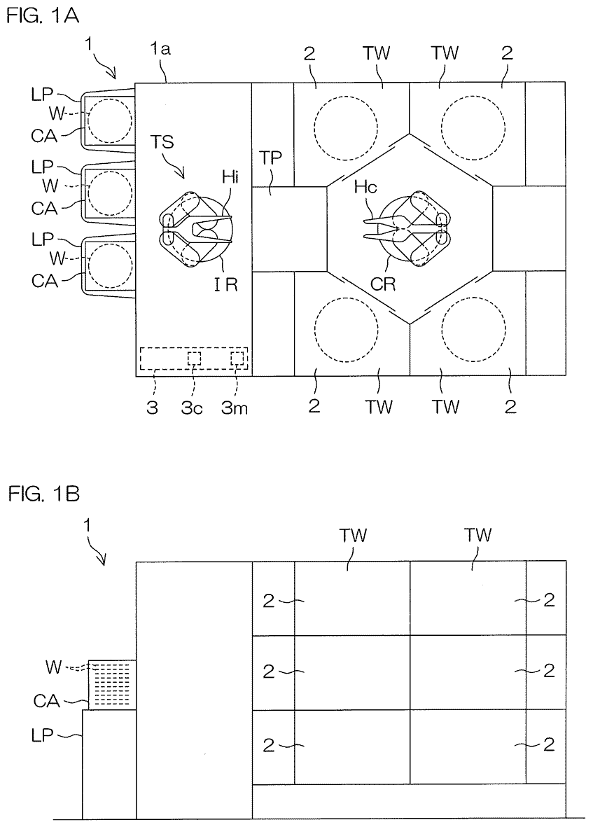

FIG. 1A is a schematic plan view showing a layout of a substrate processing apparatus 1 according to a preferred embodiment of the present invention. FIG. 1B is a schematic side view of the substrate processing apparatus 1. The substrate processing apparatus 1 is a single substrate processing type apparatus that processes disk-shaped substrates W such as semiconductor wafers one by one. The substrate processing apparatus 1 includes a load port LP that holds a carrier CA housing the substrates W, a plurality of processing units 2 that process the substrates W transferred from the carrier CA on the load port LP with a processing fluid such as a processing liquid or a processing gas, a transfer system T5 that transfers the substrates W between the carrier CA on the load port LP and the plurality of processing units 2, an outer wall 1a that forms a sealed space housing the plurality of processing units 2 and the transfer system TS, and a controller 3 that controls the substrate processing apparatus 1.

The plurality of processing units 2 form a plurality of towers TW. FIG. 1A shows an example where four towers TW are formed. As shown in FIG. 1B, a plurality of processing units 2 included in a single tower TW are stacked vertically. As shown in FIG. 1A, the plurality of towers TW form two rows extending in the depth direction (the left-right direction of the paper in FIG. 1A) of the substrate processing apparatus 1 in a plan view. The two rows face each other across a transport path TP in a plan view.

The transport system TS includes an indexer robot IR that transports the substrate W between the carrier CA on the load port LP and the plurality of processing units 2, and a center robot CR that transports the substrate W between the indexer robot IR and the plurality of processing units 2. The indexer robot IR is disposed between the load port LP and the center robot CR, in a plan view. The center robot CR is disposed in the transport path TP.

The indexer robot IR includes one or more hands Hi that support the substrates W horizontally. The hand Hi is movable in parallel in both the horizontal direction and the vertical direction. The hand Hi is rotatable around a vertical line. The hand Hi can carry in and carry out the substrate W to and from the carrier CA on any of the load ports LP, and can receive and transfer the substrate W from and to the center robot CR.

The center robot CR includes one or more hands Hc that support the substrates W horizontally. The hand Hc is movable in parallel in both the horizontal direction and the vertical direction. The hand Hc is rotatable around a vertical line. The hand Hc can receive and transfer the substrate W from and to the indexer robot IR, and carry in and carry out the substrate W to and from any of the processing units 2.

The controller 3 controls electrical devices and electronic devices provided in the substrate processing apparatus 1. The controller 3 includes at least one computer. The computer includes a memory 3m that stores information such as a program, and a CPU 3c (Central Processing Unit) that controls the substrate processing apparatus 1 according to the program stored in the memory 3m. The controller 3 controls the substrate processing apparatus 1 to carry out transfer and processing of the substrate W described below. In other words, the controller 3 is programmed to carry out transfer and processing of the substrate W as described below.

Next, a processing unit 2 will be described.

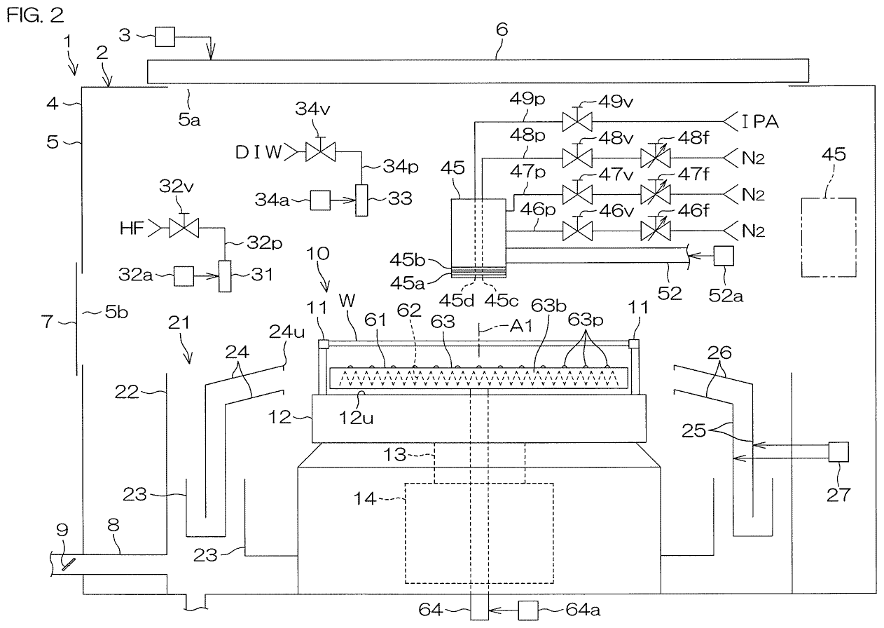

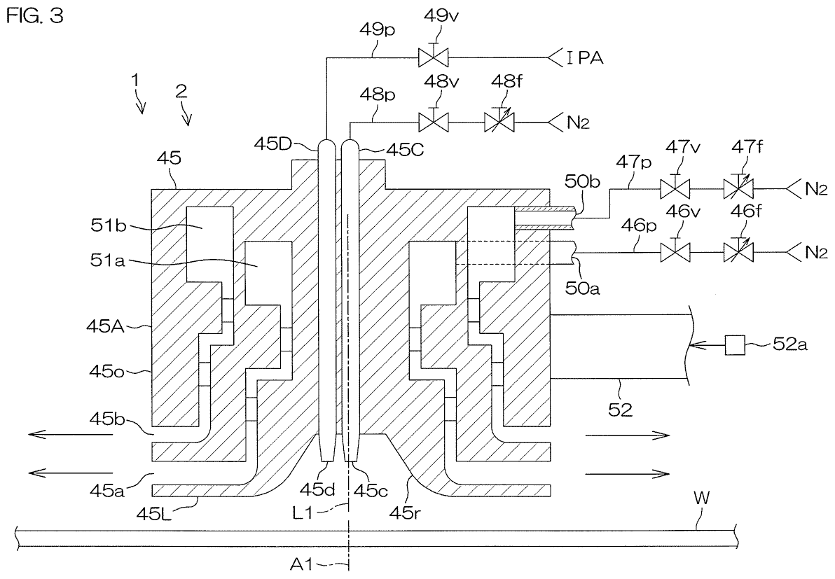

FIG. 2 is a schematic view of an interior of the processing unit 2 provided in the substrate processing apparatus 1 when viewed horizontally. FIG. 3 is a schematic view showing a vertical cross-section of a fluid nozzle 45 provided in the processing unit 2.

As shown in FIG. 2, the processing unit 2 includes a box-shaped chamber 4 having an interior space, a spin chuck 10 that rotates one substrate W around a vertical rotational axis A1 passing through the central portion of the substrate W while holding the substrate W horizontally in the chamber 4, and a tubular processing cup 21 surrounding the spin chuck 10 around the rotational axis A1.

The chamber 4 includes a box-shaped partition 5 provided with a carry-in and carry-out opening 5b through which the substrate W passes, and a door 7 that opens and closes the carry-in and carry-out opening 5b. An FFU 6 (fan filter unit) is disposed on an air outlet 5a provided in the upper portion of the partition 5. The FFU 6 constantly supplies clean air (air that has been filtered by a filter) from the air outlet 5a to the chamber 4. The gas in the chamber 4 is discharged from the chamber 4 through a discharged gas duct 8 connected to the bottom portion of the processing cup 21. Thereby, a downflow of clean air is constantly formed inside the chamber 4. The flow rate of discharged gas to be discharged into the discharged gas duct 8 is changed according to the opening degree of a discharged gas valve 9 located in the discharged gas duct 8.

The spin chuck 10 includes a disk-shaped spin base 12 horizontally held, a plurality of chuck pins 11 that hold the substrate W horizontally above the spin base 12, a spin shaft 13 extending downward from the central portion of the spin base 12, and a spin motor 14 that rotates the spin base 12 and the plurality of chuck pins 11 by rotating the spin shaft 13.

The spin chuck 10 is not limited to a gripping-type chuck that contacts the plurality of chuck pins 11 with the end surface of substrate W, and may be a vacuum-type chuck that holds the substrate W horizontally by adsorbing the rear surface (lower surface) of the substrate W, which is a non-device forming surface, onto the upper surface 12u of the spin base 12. When the spin chuck 10 is the gripping-type chuck, the plurality of chuck pins 11 correspond to a substrate holder. When the spin chuck 10 is the vacuum-type chuck, the spin base 12 corresponds to the substrate holder.

The processing cup 21 includes a plurality of guards 24 that receive processing liquid discharged outward from the substrate W held by the spin chuck 10, a plurality of cups 23 that receive the processing liquid guided downward by the plurality of guards 24, and a tubular outer wall 22 surrounding the plurality of guards 24 and the plurality of cups 23. FIG. 2 shows an example where two guards 24 and two cups 23 are provided and the outer cup 23 is integral with the inner guard 24.

The guard 24 includes a cylindrical portion 25 surrounding the spin chuck 10, and a toric ceiling portion 26 extending upward obliquely from the upper end portion of the cylindrical portion 25 toward the rotational axis A1. The plurality of ceiling portions 26 overlap in the vertical direction, and the plurality of cylindrical portions 25 are disposed in a concentric manner. The toric upper end of the ceiling portion 26 corresponds to the upper end 24u of the guard 24 surrounding the substrate W and the spin base 12 in a plan view. The plurality of cups 23 are disposed under the plurality of cylindrical portions 25, respectively. The cup 23 forms an annular groove that receives processing liquid guided downward by the guard 24.

The processing unit 2 includes a guard raising/lowering unit 27 that individually raises and lowers the plurality of guards 24. The guard raising/lowering unit 27 positions the guard 24 at any position within a range from an upper position to a lower position. FIG. 2 shows a state where two guards 24 are disposed at the lower position. The upper position is a position where the upper end 24u of the guard 24 is disposed above a holding position where the substrate W held by the spin chuck 10 is positioned. The lower position is a position where the upper end 24u of the guard 24 is disposed below the holding position.

The actuator is a device that converts driving energy, which represents electrical, fluid, magnetic, thermal or chemical energy, to mechanical work, that is, motion of a tangible object. The actuator includes an electric motor (rotary motor), linear motor, air cylinder and other devices. If the motion of the actuator is different from the motion of the object, a motion converter may be provided to convert the motion of the actuator into linear motion or rotation. For example, if the actuator is an electric motor and the object is to be moved in a linear motion, a motion converter, such as a ball screw and ball nut, may convert the rotation of the electric motor into linear motion.

The processing unit 2 includes a chemical liquid nozzle 31 that discharges a chemical liquid toward the upper surface of the substrate W held by the spin chuck 10, a rinse liquid nozzle 33 that discharges a rinse liquid toward the upper surface of the substrate W held by the spin chuck 10. FIG. 2 shows an example where the chemical liquid is HF (hydrofluoric acid) and the rinse liquid is DIW (pure water).

The chemical liquid nozzle 31 is connected to a chemical liquid piping 32p that guides the chemical liquid. When a chemical liquid valve 32v attached to the chemical liquid piping 32p is opened, an outlet of the chemical liquid nozzle 31 continuously discharges the chemical liquid downwardly. The chemical liquid may be a liquid that contains at least one of sulfuric acid, nitric acid, hydrochloric acid, hydrofluoric acid, phosphorus acid, acetic acid, ammonia water, a hydrogen peroxide solution, organic acid (e.g., citric acid, oxalic acid or the like), organic alkaline (e.g., TMAH: tetramethyl ammonium hydroxide or the like), a surface-active agent, and a corrosion inhibitor, may be a liquid other than this.

Although not shown, the chemical liquid valve 32v includes a valve body provided with an annular valve seat through which the chemical liquid passes, a valve element that is movable with respect to the valve seat, and an actuator that moves the valve element between a closed position where the valve element contacts the valve seat and an open position where the valve element is away from the valve seat. The same applies to other valves. The actuator may be a pneumatic actuator or an electric actuator, or may be an actuator other than these. The controller 3 opens and closes the chemical liquid valve 32v and the like by controlling the actuator.

The rinse liquid nozzle 33 is connected to a rinse liquid pipe 34p that guides the rinse liquid. When a rinse liquid valve 34v attached to the rinse liquid pipe 34p is opened, an outlet of the rinse liquid nozzle 33 continuously discharges the rinse liquid downward. The rinse liquid may be any of pure water (deionized water (DIW)), carbonated water, electrolyzed ionized water, hydrogen water, ozone water, and hydrochloric acid solution having a dilution concentration (for example, about 10 to 100 ppm), or may be a liquid other than these.

The chemical liquid nozzle 31 may be a scan nozzle that moves a collision position of the chemical liquid with respect to the substrate W within the upper surface of the substrate W or may be a fixed nozzle that cannot move the collision position of the chemical liquid with respect to the substrate W. The same applies to other nozzles. FIG. 2 shows an example where the chemical liquid nozzle 31 and the rinse liquid nozzle 33 are scan nozzles.

The chemical liquid nozzle 31 is connected to a nozzle actuator 32a that moves the chemical liquid nozzle 31 in at least one direction of the vertical direction and the horizontal direction. The rinse liquid nozzle 33 is connected to a nozzle actuator 34a that moves the rinse liquid nozzle 33 in at least one direction of the vertical direction and the horizontal direction. The nozzle actuator 32a horizontally moves the chemical liquid nozzle 31 between a processing position where the chemical liquid discharged from the chemical liquid nozzle 31 is supplied to the upper surface of the substrate W and a standby position where the chemical liquid nozzle 31 is positioned around the processing cup 21 in a plan view. The same applies to the nozzle actuator 34a.

The processing unit 2 includes a fluid nozzle 45 that discharges processing fluid above the substrate W being held by the spin chuck 10. The fluid nozzle 45 includes a solvent discharge port 45d that discharges an organic solvent toward the upper surface of the substrate W being held by the spin chuck 10, a central discharge port 45c that discharges gas toward the upper surface of the substrate W, and at least one annular discharge port that discharges gas in a radial manner above the substrate W. FIG. 2 shows an example where two annular discharge ports, a first annular discharge port 45a and a second annular discharge port 45b, are provided.

As shown in FIG. 3, the fluid nozzle 45 includes a solvent nozzle 45D that has formed the solvent discharge port 45d, a first gas nozzle 45C that has formed the central discharge port 45c, and a second gas nozzle 45A that has formed the first annular discharge port 45a and second annular discharge port 45b. FIG. 3 shows an example in which the second gas nozzle 45A is a single integral member, and the solvent nozzle 45D and first gas nozzle 45C are separate members held by the second gas nozzle 45A, and separate from the second gas nozzle 45A. The second gas nozzle 45A may also be constructed of multiple mutually anchored members. The solvent nozzle 45D may also be integral with at least a portion of the second gas nozzle 45A. The same applies to the first gas nozzle 45C.

The fluid nozzle 45 includes a cylindrical outer peripheral surface 45o surrounding the vertical center line Li of the fluid nozzle 45, a toric horizontal lower surface 45L running inward from the lower end of the outer peripheral surface 45o of the fluid nozzle 45, and a recessed portion 45r recessed upward from the lower surface 45L of the fluid nozzle 45, on the inside of the lower surface 45L of the fluid nozzle 45. The outer peripheral surface 45o of the fluid nozzle 45 corresponds to the outer peripheral surface of the second gas nozzle 45A. The lower surface 45L of the fluid nozzle 45 corresponds to the lower surface of the second gas nozzle 45A. The solvent discharge port 45d and central discharge port 45c are disposed inside the recessed portion 45r. The first annular discharge port 45a and second annular discharge port 45b are open at the outer peripheral surface 45o of the fluid nozzle 45. The outer diameter of the fluid nozzle 45, i.e., the diameter of the outer peripheral surface 45o of the fluid nozzle 45, is smaller than the diameter of the substrate W.

The solvent nozzle 45D and first gas nozzle 45C extend up and down along the center line Li of the fluid nozzle 45. The solvent nozzle 45D and first gas nozzle 45C also protrude upward from the second gas nozzle 45A. The lower end of the solvent nozzle 45D and the lower end of the first gas nozzle 45C are disposed inside the recessed portion 45r. The solvent discharge port 45d is open at the lower end of the solvent nozzle 45D. The central discharge port 45c is open at the lower end of the first gas nozzle 45C. At least a portion of the solvent discharge port 45d may be disposed at a height equal to the central discharge port 45c, or it may be disposed above or below the central discharge port 45c. FIG. 3 shows an example where the solvent discharge port 45d and central discharge port 45c are disposed at mutually equal heights.

The solvent nozzle 45D is connected to solvent piping 49p equipped with a solvent valve 49v. When the solvent valve 49v opens, the organic solvent is supplied from the solvent piping 49p to the solvent nozzle 45D, and is discharged continuously downward from the solvent discharge port 45d of the solvent nozzle 45D. The organic solvent discharged from the solvent discharge port 45d is an organic solvent liquid. FIG. 3 shows an example where the organic solvent is IPA (isopropyl alcohol). The organic solvent discharged from the solvent discharge port 45d may be an alcohol other than IPA, or a fluorine-based organic solvent such as HFE (hydrofluoroether).

The first gas nozzle 45C is connected to a gas tube 48p equipped with a gas valve 48v and a flow rate adjustment valve 48f. When the gas valve 48v opens, gas is supplied to the first gas nozzle 45C through the gas tube 48p at a flow rate corresponding to the degree of opening of the flow rate adjustment valve 48f, and is continuously discharged downward from the central discharge port 45c of the first gas nozzle 45C. When the controller 3 (see FIG. 2) changes the degree of opening of the flow rate adjustment valve 48f, the flow rate of gas discharged from the central discharge port 45c increases or decreases. FIG. 3 shows an example in which nitrogen gas is discharged from the central discharge port 45c. The gas discharged from the central discharge port 45c may be an inert gas other than nitrogen gas, or it may be gas other than an inert gas, such as clean air or dry air.

The first annular discharge port 45a and second annular discharge port 45b are annular slits that are continuous in the circumferential direction of the fluid nozzle 45 across the entire circumference of the fluid nozzle 45. The second annular discharge port 45b is disposed higher than the first annular discharge port 45a. When the fluid nozzle 45 is disposed at the central upper position and central lower position (explained below), the center line Li of the fluid nozzle 45 is disposed on the rotational axis A1 of the substrate W. The first annular discharge port 45a and second annular discharge port 45b surround the rotational axis A1 of the substrate W. The diameters of the first annular discharge port 45a and second annular discharge port 45b are smaller than the outer diameter of the substrate W. The diameters of the first annular discharge port 45a and second annular discharge port 45b may be equal, or they may be different from each other.

At least a portion of the first annular discharge port 45a may be disposed at a height equal to the solvent discharge port 45d, or it may be disposed above or below the solvent discharge port 45d. At least a portion of the first annular discharge port 45a may be disposed at a height equal to the central discharge port 45c, or it may be disposed above or below the central discharge port 45c. The same applies to the second annular discharge port 45b. FIG. 3 shows an example where at least a portion of the first annular discharge port 45a is disposed lower than the solvent discharge port 45d and central discharge port 45c, with the entirety of the second annular discharge port 45b disposed higher than the solvent discharge port 45d and central discharge port 45c.

The first annular discharge port 45a is connected to a first gas tube 46p equipped with a first gas valve 46v and a first flow rate adjustment valve 46f. The second annular discharge port 45b is connected to a second gas tube 47p equipped with a second gas valve 47v and a second flow rate adjustment valve 47f. When the first gas valve 46v opens, gas is supplied to the first annular discharge port 45a through the first gas tube 46p at a flow rate corresponding to the degree of opening of the first flow rate adjustment valve 46f, and is discharged from the first annular discharge port 45a. Likewise, when the second gas valve 47v opens, gas is supplied to the second annular discharge port 45b through the second gas tube 47p at a flow rate corresponding to the degree of opening of the second flow rate adjustment valve 47f, and is discharged from the second annular discharge port 45b. FIG. 3 shows an example where nitrogen gas is discharged from the first annular discharge port 45a and the second annular discharge port 45b.

When the first annular discharge port 45a discharges gas, an airflow is formed spreading out in a radial manner from the first annular discharge port 45a. Likewise, when the second annular discharge port 45b discharges gas, an airflow is formed spreading out in a radial manner from the second annular discharge port 45b. Most of the gas discharged from the first annular discharge port 45a runs below the gas discharged from the second annular discharge port 45b. Therefore, when both the first gas valve 46v and the second gas valve 47v are opened, multiple airflows overlapping above and below are formed around the fluid nozzle 45.

FIG. 3 shows an example where both the first annular discharge port 45a and the second annular discharge port 45b discharge gas in a radial manner in the horizontal direction. Either or both the first annular discharge port 45a and second annular discharge port 45b may discharge gas in a radial manner obliquely downward. In this case, when the fluid nozzle 45 is disposed at any location in the region from the central upper position to the central lower position, either or both the first annular discharge port 45a and second annular discharge port 45b may discharge gas in a radial manner obliquely downward toward the annular region within the upper surface of the substrate W around the center of the substrate W.

As shown in FIG. 3, the fluid nozzle 45 includes a first inlet 50a that is open at the front surface of the fluid nozzle 45 and a first gas channel 51a that guides gas from the first inlet 50a to the first annular discharge port 45a. The fluid nozzle 45 also includes a second inlet 50b that is open at the front surface of the fluid nozzle 45 and a second gas channel 51b that guides gas from the second inlet 50b to the second annular discharge port 45b. The gas inside the first gas tube 46p flows into the first gas channel 51a through the first inlet 50a, and is guided by the first gas channel 51a to the first annular discharge port 45a. Similarly, the gas inside the second gas tube 47p flows into the second gas channel 51b through the second inlet 50b, and is guided by the second gas channel 51b to the second annular discharge port 45b.

The first inlet 50a and second inlet 50b are disposed higher than the first annular discharge port 45a and second annular discharge port 45b. The first gas channel 51a extends from the first inlet 50a to the first annular discharge port 45a, while the second gas channel 51b extends from the second inlet 50b to the second annular discharge port 45b. As shown in FIG. 3, the first gas channel 51a and second gas channel 51b are cylindrical around the vertical center line Li of the fluid nozzle 45. The first gas channel 51a and second gas channel 51b are disposed in a concentric manner. The first gas channel 51a is surrounded by the second gas channel 51b.

The processing unit 2 includes a nozzle arm 52 that holds the fluid nozzle 45, and a nozzle actuator 52a that moves the fluid nozzle 45 in the vertical direction and horizontal direction by moving the nozzle arm 52. The nozzle arm 52 is connected to the fluid nozzle 45 at a location higher than the first annular discharge port 45a and second annular discharge port 45b. When the nozzle actuator 52a moves the second gas nozzle 45A, the solvent nozzle 45D and the first gas nozzle 45C also moves.

The nozzle actuator 52a moves the fluid nozzle 45 horizontally between the central upper position (the position shown in FIG. 2) and a standby position (the location indicated by an alternate long and two short dashed line in FIG. 2). The nozzle actuator 52a also moves the fluid nozzle 45 vertically between the central upper position and the central lower position (the position shown in FIG. 3). The standby position is the location where the fluid nozzle 45 is located around the processing cup 21 in a plan view. The central upper position and central lower position are positions where the fluid nozzle 45 overlaps with the central portion of the substrate W in a plan view. The central upper position is the position above the central lower position. When the fluid nozzle 45 is disposed at the central lower position, the distance from the upper surface of the substrate W to the lower surface 45L of the fluid nozzle 45 in the vertical direction may be smaller than the radius of the fluid nozzle 45, or it may be larger than the radius.

Hereinafter, the central upper position and central lower position may be collectively referred to as “center position.” When the fluid nozzle 45 is disposed at the center position, the fluid nozzle 45 overlaps with the central portion of the upper surface of the substrate W in a plan view. However, since the fluid nozzle 45 is smaller than the substrate W in a plan view, the parts of the upper surface of the substrate W other than the central portion do not overlap with the fluid nozzle 45 in a plan view. When the fluid nozzle 45 is disposed at the center position, and either or both the first gas valve 46v and second gas valve 47v are opened, the airflow spreading radially from the fluid nozzle 45 flows above each section of the upper surface of the substrate W other than the central portion. The entire upper surface of the substrate W is thus protected by the fluid nozzle 45 and airflow.

As shown in FIG. 2, the processing unit 2 includes a hot plate 61 as an example of a heater that heats the substrate W being held by the spin chuck 10. The hot plate 61 is disposed between the substrate W that is being supported by the plurality of chuck pins 11, and the spin base 12. The hot plate 61 is capable of parallel vertical movement above the spin base 12, between the upper position and lower position (the position shown in FIG. 2). The substrate W is transferred between the plurality of chuck pins 11 and the hot plate 61 by raising or lowering of the hot plate 61. The hot plate 61 is an example of a substrate holder.

The hot plate 61 includes a heating unit 62 that generates Joule heat when energized, and an outer case 63 that houses the heating unit 62. The outer case 63 is disposed between the substrate W that is being supported by the plurality of chuck pins 11, and the spin base 12. The temperature of the heating unit 62 is changed by a controller 3. When the controller 3 causes the heating unit 62 to release heat, the entire substrate W becomes uniformly heated.

The outer case 63 of the hot plate 61 includes a discoid base portion 63b disposed below the substrate W being supported by the plurality of chuck pins 11, and a plurality of hemispherical protrusion portions 63p protruding upward from the upper surface of the base portion 63b. The upper surface of the base portion 63b is parallel with the lower surface of the substrate W and has an outer diameter that is smaller than the diameter of the substrate W. The plurality of protrusion portions 63p contact the lower surface of the substrate W at a location that is at a distance above the upper surface of the base portion 63b. The plurality of protrusion portions 63p are disposed at a plurality of locations within the upper surface of the base portion 63b, so that the substrate W is supported horizontally. The substrate W is supported horizontally in a state such that the lower surface of the substrate W is at a distance above the upper surface of the base portion 63b.

The hot plate 61 is supported horizontally by a support shaft 64 extending downward from the central portion of the hot plate 61. The plurality of chuck pins 11 are disposed around the hot plate 61. The center line of the hot plate 61 is disposed on the rotational axis A1 of the substrate W. The hot plate 61 does not rotate even when the spin chuck 10 rotates. The outer diameter of the hot plate 61 is smaller than the diameter of the substrate W.

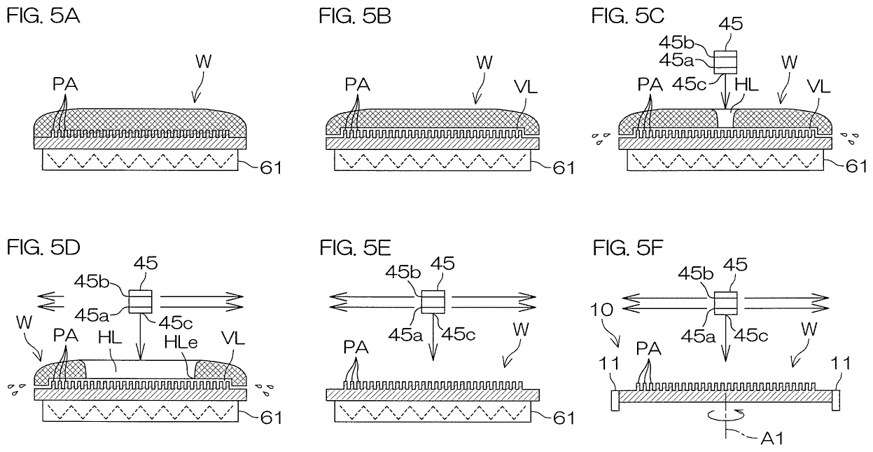

The hot plate 61 is connected to a plate raising/lowering actuator 64a via the support shaft 64. The plate raising/lowering actuator 64a vertically raises and lowers the hot plate 61 with respect to the spin base 12, between the upper position (the position shown in FIG. 5A) and the lower position (the position shown in FIG. 2). The upper position is the contact position where the hot plate 61 contacts with the lower surface of the substrate W. The lower position is an adjacent position where the hot plate 61 is located between the lower surface of the substrate W and the upper surface 12u of the spin base 12, and away from the substrate W.

The plate raising/lowering actuator 64a positions the hot plate 61 at a desired position in a range between the upper position and the lower position. When the hot plate 61 rises to the upper position with the substrate W supported on the plurality of chuck pins 11 and all of the chuck pins 11 disposed at the open position, the plurality of protrusion portions 63p of the hot plate 61 contact with the lower surface of the substrate W, so that the substrate W is raised up by the hot plate 61. This causes the substrate W to move upward away from the plurality of chuck pins 11.

When the hot plate 61 is lowered with the substrate W supported on the hot plate 61 located at the upper position and all of the chuck pins 11 disposed at the open position, the substrate W on the hot plate 61 is placed on the plurality of chuck pins 11 before the hot plate 61 reaches the lower position, so that the hot plate 61 moves downward away from the substrate W. In this way, the substrate W is transferred between the plurality of chuck pins 11 and the hot plate 61.

An example of processing of a substrate W by the substrate processing apparatus 1 will now be explained.

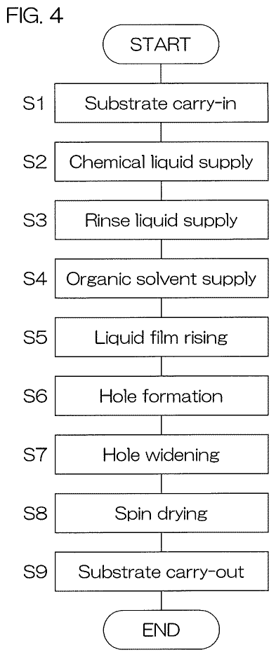

FIG. 4 is a process chart for describing an example of processing of the substrate W performed by the substrate processing apparatus 1. FIG. 5A, FIG. 5B, FIG. 5C, FIG. 5D, FIG. 5E and FIG. 5F are schematic cross-sectional views showing states of the substrate W when the example of processing shown in FIG. 4 is being performed. In FIG. 5A to FIG. 5D, the cross hatched regions represent an IPA liquid film. The following explanation refers to FIG. 2 and FIG. 4. FIG. 5A to 5F will also be referred to as appropriate.

The substrate W being processed is a semiconductor wafer such as silicon wafer, for example. The front surface of the substrate W corresponds to the device-forming side where a device such as a transistor or capacitor is to be formed. The substrate W may be a substrate W having a pattern PA (see FIG. 5A) formed on the front surface of the substrate W, or it may be a substrate W without a pattern PA formed on the front surface of the substrate W. In the latter case, a pattern PA may be formed by a chemical liquid supply step as described below.

When a substrate W is to be processed by the substrate processing apparatus 1, a carry-in step is performed in which the substrate W is carried into the chamber 4 (step S1 of FIG. 4).

Specifically, with all of the guards 24 located at the lower position and all of the scan nozzles located at the standby position, the center robot CR (see FIG. 1A) supports the substrate W with the hand Hc while causing the hand Hc to enter into the chamber 4. The center robot CR places the substrate W on the hand Hc onto the plurality of chuck pins 11, with the front surface of the substrate W facing upward. The plurality of chuck pins 11 are then pressed against the edges of the substrate W, by which the substrate W is held. The center robot CR retracts the hand Hc from the interior of the chamber 4 after the substrate W has been placed on the spin chuck 10.

After the substrate W has been held on the spin chuck 10, a chemical liquid supply step is carried out in which chemical liquid is supplied onto the upper surface of the substrate W to form a liquid film of the chemical liquid covering the entire upper surface of the substrate W (step S2 of FIG. 4).

Specifically, the nozzle actuator 32a moves a chemical liquid nozzle 31 from a standby position to the processing position. The guard raising/lowering actuator 27 raises at least one of the guards 24 from the lower position to the upper position. A spin motor 14 begins rotation of the substrate W. This causes the substrate W to rotate at the chemical liquid supply rate. Raising of the guard 24 may be initiated at the same time the chemical liquid nozzle 31 reaches the processing position, or it may be initiated before or after it reaches the processing position. The same also applies to the timing of initiating rotation of the substrate W.

With the chemical liquid nozzle 31 located at the processing position, at least one of the guards 24 located at the upper position and the substrate W rotating at the chemical liquid supply rate, a chemical liquid valve 32v is opened and discharge of chemical liquid by the chemical liquid nozzle 31 begins. The chemical liquid that has been discharged from the chemical liquid nozzle 31 collides with the upper surface of the substrate W that is rotating at the chemical liquid supply rate, and then flows outward along the upper surface of the substrate W. This causes the chemical liquid to be supplied over the entire upper surface of the substrate W, so that a liquid film of the chemical liquid is formed covering the entire upper surface of the substrate W.

When a prescribed time period has elapsed after the chemical liquid valve 32v has been opened, the chemical liquid valve 32v is closed and discharge of the chemical liquid is stopped. The nozzle actuator 32a then moves the chemical liquid nozzle 31 to the standby position. When the chemical liquid nozzle 31 discharges the chemical liquid, the nozzle actuator 32a may move the collision position of the chemical liquid on the upper surface of the substrate W so that the collision position passes through the central portion and the outer peripheral section, or it may stop the collision position at the central portion. The option of whether or not to move the collision position applies to the processing liquid supplied to the upper surface of the substrate W after the chemical liquid.

After the chemical liquid has been supplied to the substrate W, a rinse liquid supply step is carried out in which pure water (an example of rinse liquid) is supplied to the upper surface of the substrate W to wash off the chemical liquid on the substrate W with the pure water (step S3 in FIG. 4).

Specifically, the nozzle actuator 34a moves the rinse liquid nozzle 33 from the standby position to the processing position, with one or more of the guards 24 located at the upper position. The rinse liquid valve 34v is then opened and the rinse liquid nozzle 33 begins discharge of the rinse liquid. Before discharge of the pure water begins, the guard raising/lowering actuator 27 may move one or more of the guards 24 vertically in order to switch the guard 24 blocking the liquid discharged from the substrate W.

The pure water that has been discharged from the rinse liquid nozzle 33 collides with the upper surface of the substrate W that is rotating at the rinse liquid supply rate, and then flows outward along the upper surface of the substrate W. The rinse liquid supply rate may be the same as or different from the chemical liquid supply rate. The chemical liquid on the substrate W is replaced with the pure water that has been discharged from the rinse liquid nozzle 33. This causes a liquid film of the pure water to be formed covering the entire upper surface of the substrate W. When a prescribed time period has elapsed after the rinse liquid valve 34v has been opened, the rinse liquid valve 34v is closed and discharge of the rinse liquid is stopped. The nozzle actuator 34a then moves the rinse liquid nozzle 33 to the standby position.

After the pure water has been supplied to the substrate W, an organic solvent supply step is carried out in which IPA (an example of an organic solvent) is supplied to the upper surface of the substrate W to replace the liquid film of the rinse liquid on the substrate W with the IPA liquid film (step S4 in FIG. 4).

Specifically, the nozzle actuator 52a moves the fluid nozzle 45 from the standby position to the center position, with one or more of the guards 24 located at the upper position. The solvent valve 49v is then opened and the solvent discharge port 45d of the fluid nozzle 45 initiates discharge of IPA. Before discharge of the IPA begins, the guard raising/lowering actuator 27 may move one or more of the guards 24 vertically in order to switch the guard 24 blocking the liquid discharged from the substrate W.

The IPA that has been discharged from the solvent discharge port 45d of the fluid nozzle 45 collides with the upper surface of the substrate W that is rotating at the solvent supply rate, and then flows outward along the upper surface of the substrate W. The solvent supply rate may be the same as or different from the rinse liquid supply rate. The pure water on the substrate W is replaced with the IPA discharged from the solvent discharge port 45d. This causes a liquid film of the IPA to be formed covering the entire upper surface of the substrate W (see FIG. 5A). When a prescribed time period has elapsed after the solvent valve 49v has been opened, the solvent valve 49v is closed and discharge of the IPA is stopped.

During the period from start of the organic solvent supply step until completion of the spin drying step described below, the fluid nozzle 45 is located at the center position. Whether the fluid nozzle 45 stops at the central upper position or central lower position, and the timing at which it moves between the central upper position and central lower position, will be described below.

After the liquid film of the pure water has been replaced with the liquid film of IPA, a paddle step may be carried out in which the IPA is allowed to remain on the upper surface of the substrate W while maintaining the state in which the entire upper surface of the substrate W is covered with the liquid film of IPA.

Specifically, the rotational speed of the substrate W may be lowered to the paddle speed (for example, a speed of greater than 0 and 50 rpm or lower), or zero, while the entire upper surface of the substrate W is covered with the liquid film of IPA. This will allow the IPA to remain on the upper surface of the substrate W without moving or substantially without moving with respect to the upper surface of the substrate W. When the rotational speed of the substrate W is lowered to zero, the substrate W may be supported on the hot plate 61 by raising the hot plate 61 to the upper position, while holding of the substrate W by the plurality of chuck pins 11 is released. While the substrate W is rotating at the paddle speed or resting, fresh IPA may either be continuously supplied to the upper surface of the substrate W, or it may be stopped.

After the IPA has been supplied to the substrate W, a liquid film raising step is carried out in which a vapor layer VL of IPA that causes the liquid film of IPA to rise up from the upper surface of the substrate W (see FIG. 5B) is formed between the liquid film of IPA and the upper surface of the substrate W (step S5 of FIG. 4).

Specifically, the hot plate 61 releases heat while the substrate W is disposed above the hot plate 61, and heating of the substrate W begins. Heat release by the hot plate 61 may begin before or after IPA is supplied to the substrate W, or it may begin simultaneously with supply of IPA to the substrate W. The hot plate 61 may heat the substrate W while it is in contact with the lower surface of the substrate W, or it may heat the substrate W while separated from the lower surface of the substrate W. The temperature of the substrate W may be changed by changing the temperature of the hot plate 61, or it may be changed by changing the distance between the substrate W and the hot plate 61.

When the hot plate 61 is to heat the substrate W while in contact with the lower surface of the substrate W, the substrate W stops over the hot plate 61. When the hot plate 61 is to heat the substrate W while separated from the lower surface of the substrate W, the spin chuck 10 rotates the substrate W at a liquid discharge speed. The liquid discharge speed is greater than the paddle speed. The liquid discharge speed may be the same as or different from the solvent supply rate.

When supply of electric power to the hot plate 61 is initiated, the entirety or substantially the entirety of the upper surface of the hot plate 61 releases heat. The substrate W can therefore be more uniformly heated than when a heating fluid such as hot water is discharged toward the central portion of the lower surface of the substrate W. The IPA on the upper surface of the substrate W is heated by the hot plate 61, via the substrate W. The temperature of the hot plate 61 during heating of the substrate W may be any value, so long as it is higher than room temperature (20 to 30° C.). The temperature of the hot plate 61 may be equal to or different from the boiling point of the liquid on the substrate W (IPA in this example).

If the temperature of the upper surface of the substrate W (including the front surface of the pattern PA when a pattern PA has been formed) is at or above the boiling point of IPA, then the IPA will gasify at the interface between the IPA and substrate W, generating numerous small air bubbles at the interface between the IPA and substrate W. When IPA gasifies at any locations of the interface between the IPA and substrate W, a vapor layer VL containing the IPA vapor (see FIG. 5B) is formed between the IPA and substrate W. This causes the liquid film of IPA to separate from the upper surface of the substrate W, so that the liquid film of IPA rises up from the upper surface of the substrate W (which is the upper surface of the pattern PA when a pattern PA has been formed). During this time, friction resistance on the liquid film of IPA from the substrate W is small enough to be considered zero.

After the liquid film of IPA has been lifted up from the upper surface of the substrate W, a liquid discharge step is carried out in which the liquid film of IPA is discharged from the upper surface of the substrate W. The liquid discharge step includes a hole forming step in which an exposing hole HL which exposes the central portion of the upper surface of the substrate W through the liquid film of IPA, is formed at the central portion of the liquid film of IPA (step S6 of FIG. 4), and a hole widening step in which the outer edge HLe of the exposing hole HL (see FIG. 5D) is widened to the outer perimeter of the upper surface of the substrate W (step S7 of FIG. 4).

When forming the exposing hole HL, the fluid nozzle 45 is located at the center position and the gas valve 48v is opened with at least one guard 24 located at the upper position, thus initiating discharge of the inert gas by the central discharge port 45c of the fluid nozzle 45. The temperature of the inert gas discharged from the central discharge port 45c may be room temperature, or it may be higher than room temperature. The inert gas discharged from the central discharge port 45c, after having collided with the liquid film of IPA at the central portion of the upper surface of the substrate W, flows outward in all directions along the front surface of the liquid film of IPA. This reduces the thickness of the liquid film of IPA at the central portion, forming an substantially circular exposing hole HL at the central portion of the liquid film of IPA (see FIG. 5C). The force of moving the IPA outward is also applied from the inert gas to the IPA on the substrate W, causing the IPA to flow outward along the upper surface of the substrate W.

When the exposing hole HL is formed, the liquid film of IPA is converted from a circular shape to a ring shape that is concentric with the outer perimeter of the substrate W. The IPA flows down from the outer perimeter of the upper surface of the substrate W. Accordingly, the inner diameter of the ring-shaped liquid film of IPA continuously increases to be equal to the outer diameter of the upper surface of the substrate W. In other words, the outer edge HLe of the exposing hole HL widens to the outer perimeter of the upper surface of the substrate W, without stopping, and substantially circular and concentric with the outer perimeter of the substrate W (see FIG. 5D). All of the IPA on the substrate W is discharged from the upper surface of the substrate W during this time, while connected and without splitting. This removes droplets of visible size from the upper surface of the substrate W, thus exposing the entire upper surface of the substrate W (see FIG. SE).

After all of the liquid film of IPA has disappeared from the upper surface of the substrate W, a spin drying step is carried out in which the substrate W is dried by high-speed rotation of the substrate W (step S8 of FIG. 4).

Specifically, while the hot plate 61 is supporting the lower surface of the substrate W, the substrate W is delivered from the hot plate 61 to the plurality of chuck pins 11, and the plurality of chuck pins 11 then hold the substrate W. In this state, the spin chuck 10 rotates the substrate W at a drying speed (see FIG. 5F). The drying speed may be the same as or different from the solvent supply rate. Even if droplets of invisible size remain on the upper surface of the substrate W, the droplets evaporate while the substrate W is rotating at the drying speed. The substrate W is thus dried. When a prescribed time period has elapsed after initiating high-speed rotation of the substrate W, the spin chuck 10 stops the rotation. This causes rotation of the substrate W to be halted. During at least part of the period while the substrate W is rotating at the drying speed, the hot plate 61 may release heat to promote evaporation of the droplets.

The central discharge port 45c of the fluid nozzle 45 may halt discharge of the inert gas before initiating high-speed rotation of the substrate W, i.e., before initiating the spin drying step, or it may continuously discharge the inert gas until after initiating high-speed rotation of the substrate W. In the latter case, the central discharge port 45c may halt discharge of the inert gas at the same time rotation of the substrate W is stopped, or it may halt discharge of the inert gas before or after rotation of the substrate W is stopped.

The first annular discharge port 45a and second annular discharge port 45b of the fluid nozzle 45 may initiate discharge of the inert gas before initiating high-speed rotation of the substrate W, or it may initiate discharge of the inert gas after initiating high-speed rotation of the substrate W. In the former case, the first annular discharge port 45a and second annular discharge port 45b may initiate discharge of the inert gas at the same time that the central discharge port 45c of the fluid nozzle 45 initiates discharge of the inert gas, or it may initiate discharge of the inert gas before or after the central discharge port 45c initiates discharge of the inert gas.

When the inert gas is discharged to the central discharge port 45c of the fluid nozzle 45 while rotating the substrate W at the drying speed, the gas valve 48v is closed, either at the same time that rotation of the substrate W is stopped or before or after it is stopped. The central discharge port 45c thus stops discharge of the inert gas. When the inert gas is discharged to the first annular discharge port 45a and second annular discharge port 45b while rotating the substrate W at the drying speed, the first gas valve 46v and second gas valve 47v are closed, either at the same time that rotation of the substrate W is stopped or before or after it is stopped. The first annular discharge port 45a and second annular discharge port 45b thus stop discharge of inert gas. The nozzle actuator 52a moves the fluid nozzle 45 from the center position to the standby position after rotation of the substrate W has stopped, while the central discharge port 45c, first annular discharge port 45a and second annular discharge port 45b are not discharging inert gas.

Drying of the substrate W is followed by a carry-out step in which the substrate W is carried out from the chamber 4 (step S9 of FIG. 4).

Specifically, the guard raising/lowering actuator 27 lowers all of the guards 24 to the lower position. The center robot CR then causes the hand Hc to enter into the chamber 4. After holding of the substrate W by the plurality of chuck pins 11 has been released, the center robot CR supports the substrate W on the spin chuck 10 by the hand Hc. The center robot CR then retracts the hand Hc from inside the chamber 4 while supporting the substrate W with the hand Hc. This causes the processed substrate W to be carried out from the chamber 4.

An example of processing from formation of an exposing hole HL in a liquid film up to drying of the substrate W will now be explained.

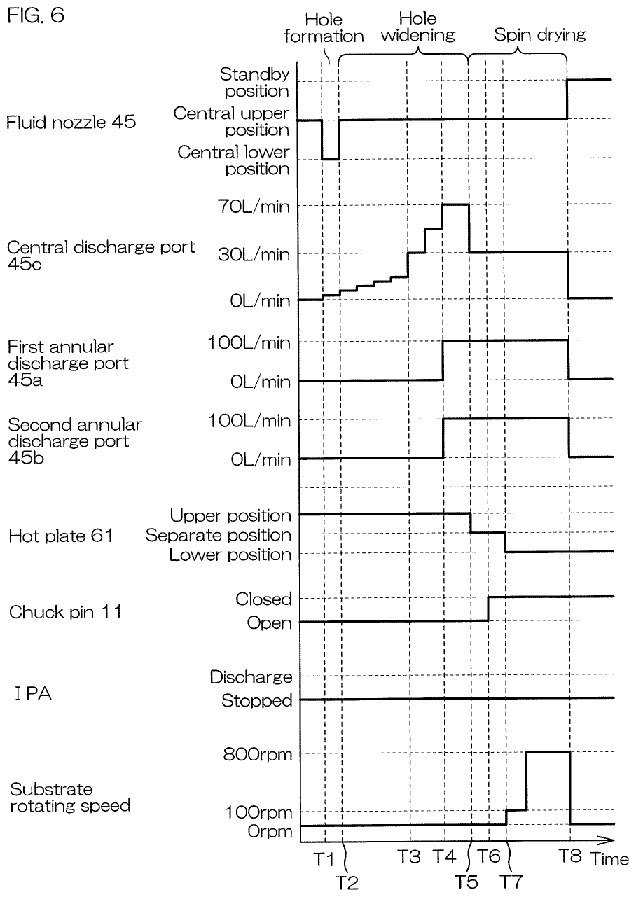

FIG. 6 is a time chart describing an example of processing from formation of an exposing hole HL in a liquid film up to drying of the substrate W. Before starting the hole forming step shown in FIG. 4 (before time T1), the fluid nozzle 45 is disposed at the central upper position, and the central discharge port 45c, first annular discharge port 45a and second annular discharge port 45b of the fluid nozzle 45 do not discharge inert gas. The substrate W is supported by the hot plate 61 which is located at the upper position, and the hot plate 61 is kept at a constant heating temperature which is higher than room temperature. A liquid film of IPA covers the entire upper surface of the substrate W, and is supported on the upper surface of the substrate W by the vapor layer VL (see FIG. 5B).

When the hole forming step shown in FIG. 4 is initiated, the fluid nozzle 45 is lowered from the central upper position to the central lower position at time T1, and discharge of the inert gas by the central discharge port 45c of the fluid nozzle 45 is initiated. FIG. 6 shows an example where discharge of the inert gas is initiated by the central discharge port 45c at the same time the fluid nozzle 45 reaches the central lower position. The central discharge port 45c may also initiate discharge of the inert gas after the fluid nozzle 45 has reached the central lower position. The central discharge port 45c continues to discharge inert gas at the hole-forming flow rate after discharge of the inert gas has been initiated. An exposing hole HL is formed in the liquid film of IPA during this time (see FIG. 5C).

After the exposing hole HL has been formed in the liquid film of IPA, the fluid nozzle 45 is raised from the central lower position to the central upper position at time T2, and the flow rate of inert gas discharged by the central discharge port 45c of the fluid nozzle 45 (hereinafter also referred to as “central gas flow rate”) is increased. FIG. 6 shows an example where the central gas flow rate is increased at the same time the fluid nozzle 45 reaches the central upper position. The central gas flow rate may also be increased after the fluid nozzle 45 has reached the central upper position.

The central gas flow rate (the flow rate of inert gas discharged from the central discharge port 45c of the fluid nozzle 45) increases stepwise or continuously from the hole-forming flow rate to the hole-widening flow rate, without decreasing. FIG. 6 shows an example in which the flow rate of inert gas increases in a stepwise manner. In this example, the hole-forming flow rate is 1.9 L/min, the hole-widening flow rate is 70 L/min, the diameter of the central discharge port 45c is 2 mm (circular) and the diameter of the substrate W is 300 mm. The period during which the central discharge port 45c continues to discharge gas at the hole-forming flow rate (the period from time T1 to time T2) is 1 second. This period is shorter than the period during which the central gas flow rate increases from the hole-forming flow rate to the hole-widening flow rate. However, the hole-widening flow rate and other rates are not limited to those specified here.

The hole-forming flow rate is the flow rate of gas discharged from the central discharge port 45c of the fluid nozzle 45 when the exposing hole HL is being formed at the central portion of the liquid film covering the entire upper surface of the substrate W. The hole-widening flow rate is the flow rate of gas discharged from the central discharge port 45c of the fluid nozzle 45 while the outer edge HLe of the exposing hole HL corresponding to the inner periphery of the ring-shaped liquid film is widening up to the outer perimeter of the upper surface of the substrate W. The hole-widening flow rate is at least the minimum flow rate of gas that can widen the outer edge HLe of the exposing hole HL up to the outer perimeter of the upper surface of the substrate W. So long as the hole-widening flow rate is greater than the hole-forming flow rate, the hole-forming flow rate may be at or above the minimum value, or it may be less than the minimum value.

In the example shown in FIG. 6, the central gas flow rate increases in a stepwise manner from the hole-forming flow rate to the hole-widening flow rate during the period from time T2 to time T4. In this example, the central gas flow rate increases in a stepwise manner by a first increase amount during the period from time T2 to time T3, and increases in a stepwise manner by a second increase amount during the period from time T3 to time T4. The second increase amount is greater than the first increase amount. The amount of increase in the flow rate of the inert gas per unit time therefore increases in a stepwise manner as time passes. The second increase amount may also be equal to or less than the first increase amount. The central gas flow rate reaches the hole-widening flow rate at time T4, with the hole-widening flow rate being maintained up to time T5.

The central gas flow rate (the flow rate of inert gas discharged from the central discharge port 45c of the fluid nozzle 45) increases up to the hole-widening flow rate while the fluid nozzle 45 is located at the central upper position. The inner diameter of the ring-shaped liquid film of IPA around the exposing hole HL increases as time passes during the period while the central discharge port 45c is discharging the inert gas. The increase in the central gas flow rate accelerates the increase in the inner diameter. The outer edge HLe of the exposing hole HL may reach the outer perimeter of the substrate W before the central gas flow rate reaches the hole-widening flow rate, or it may reach the outer perimeter of the substrate W after the central gas flow rate has reached the hole-widening flow rate.

After all of the liquid film of IPA has disappeared from the upper surface of the substrate W, the hot plate 61 is lowered from the upper position to a separate position at time T5. The plurality of chuck pins 11 are disposed at the open position when lowering of the hot plate 61 has been initiated. Therefore, the substrate W separates from the hot plate 61 while being supported by the plurality of chuck pins 11 in the open state, until the hot plate 61 reaches the separate position. Then at time T6, the plurality of chuck pins 11 are located at the closed position, and rotation of the substrate W begins at time T7.

When the plurality of chuck pins 11 have moved from the open position to the closed position (time T6), the hot plate 61 is disposed at the separate position while being kept at the heating temperature. Reduction in the temperature of the substrate W can thus be alleviated, compared to when the plurality of chuck pins 11 are moved from the open position to the closed position while the hot plate 61 is disposed at the lower position. The hot plate 61 is lowered from the separate position to the lower position at the same time that rotation of the substrate W is initiated at time T7. The hot plate 61 may also begin to be lowered from the separate position before or after rotation of the substrate W begins.

After rotation of the substrate W has begun at time T7, the rotational speed of the substrate W is increased to the drying speed, and is kept at the drying speed. FIG. 6 shows an example in which the rotational speed of the substrate W is increased in a stepwise manner up to the drying speed, via an intermediate speed. In this example, the intermediate speed is 100 rpm and the drying speed is 800 rpm. The period during which the rotational speed of the substrate W is kept at the intermediate speed may be equal to or different from the period at which the rotational speed of the substrate W is kept at the drying speed. After the rotational speed of the substrate W has been kept at the drying speed, rotation of the substrate W is stopped at time T8.

On the other hand, after the central gas flow rate (the flow rate at which inert gas is discharged from the central discharge port 45c of the fluid nozzle 45) has been kept at the hole-widening flow rate, the central gas flow rate is reduced from the hole-widening flow rate to the drying flow rate at time T5, and kept at the drying flow rate. FIG. 6 shows an example in which the central gas flow rate is kept at the drying flow rate during the period from time T5 to time T8, and reduced to zero at time T8. The drying flow rate is higher than the hole-forming flow rate and lower than the hole-widening flow rate. In the example shown in FIG. 6, the hole-forming flow rate is 1.9 L/min, the hole-widening flow rate is 70 L/min and the drying flow rate is 30 L/min. When the central gas flow rate is the drying flow rate, the substrate W may be kept at a higher temperature than room temperature, or it may be room temperature.

The fluid nozzle 45 is disposed at the central upper position during the period from time T2 to time T8. Therefore, the fluid nozzle 45 is disposed at the central upper position when the central discharge port 45c of the fluid nozzle 45 is discharging the inert gas at the drying flow rate. The fluid nozzle 45 may also discharge the inert gas from the central discharge port 45c at the drying flow rate while located at the central lower position. When the central discharge port 45c stops discharge of the inert gas at time T8, the fluid nozzle 45 simultaneously begins to move from the central upper position toward the standby position. The fluid nozzle 45 may also begin to move from the central upper position toward the standby position after the central discharge port 45c has stopped discharge of the inert gas.

When the central discharge port 45c of the fluid nozzle 45 is discharging the inert gas at the drying flow rate, all of the liquid film of IPA disappears from the upper surface of the substrate W (see FIG. 5F). The inert gas that has been discharged from the central discharge port 45c forms a columnar or linear airflow running from the central discharge port 45c to the central portion of the upper surface of the substrate W. After having collided perpendicular or substantially perpendicular with the collision position inside the central portion of the upper surface of the substrate W, the same inert gas flows outward in all directions along the upper surface of the substrate W. An outwardly directed airflow is thus formed in the region within the upper surface of the substrate W other than the central portion.

On the other hand, at the central portion of the upper surface of the substrate W, a trace amount of IPA vapor is pressed against the substrate W by the inert gas discharged from the central discharge port 45c, and may often remain there. When the vapor returns to a liquid state, it forms blemishes such as watermarks in the central portion of the upper surface of the substrate W, potentially leading to collapse of the pattern PA at the central portion of the upper surface of the substrate W. As mentioned above, the drying flow rate is lower than the hole-widening flow rate. The amount of IPA vapor remaining at the central portion of the upper surface of the substrate W can therefore be reduced compared to when the central discharge port 45c continues to discharge inert gas at the hole-widening flow rate. This can protect the entire upper surface of the substrate W by the inert gas discharged from the central discharge port 45c, while also preventing or alleviating reduction in quality of the substrate W.

FIG. 6 shows an example in which the first annular discharge port 45a and second annular discharge port 45b of the fluid nozzle 45 continue to discharge inert gas during the period from time T4 to time T8. In this example, both the first annular discharge port 45a and second annular discharge port 45b discharge inert gas at 100 L/min. The rate of the inert gas discharged from the first annular discharge port 45a is higher than the rate of the inert gas discharged from the central discharge port 45c at the drying flow rate. The same also applies to the rate of the inert gas discharged from the second annular discharge port 45b. The first annular discharge port 45a and second annular discharge port 45b may initiate discharge of inert gas before the exposing hole HL is formed in the liquid film of IPA, or they may initiate discharge of inert gas after all of the liquid film of IPA has disappeared from the upper surface of the substrate W.

When the inner diameter of the ring-shaped liquid film of IPA increases, the area of the exposed section exposed from the liquid film of IPA on the upper surface of the substrate W also increases. The exposed section inside the upper surface of the substrate W is protected not only by the inert gas discharged from the central discharge port 45c of the fluid nozzle 45, but also by the inert gas discharged from the first annular discharge port 45a and second annular discharge port 45b of the fluid nozzle 45. This allows evaporation of IPA from the substrate W to be accelerated and the amount of particles adhering to the upper surface of the substrate W can be reduced.

Next, the advantages of the preferred embodiment will be described.

According to the preferred embodiment, the gas is discharged at the hole-forming flow rate from the central discharge port 45c of the fluid nozzle 45 located above the horizontally held substrate W, toward the central portion of the upper surface of the substrate W. The exposing hole HL is thus formed in the central portion of the liquid film, and the central portion of the upper surface of the substrate W is exposed through the liquid film. Gas is then discharged from the central discharge port 45c toward the central portion of the upper surface of the substrate W, at the hole-widening flow rate which is greater than the hole-forming flow rate. This increases the rate of gas discharged from the central discharge port 45c, compared to when the central discharge port 45c discharges gas at the hole-forming flow rate.

The gas discharged from the central discharge port 45c collides with the upper surface of the substrate W inside the exposing hole HL and then flows outward in all directions along the upper surface of the substrate W. The IPA, as an example of processing liquid, is pushed outward by the gas. Moreover, since the flow rate of gas discharged from the central discharge port 45c is higher than when the exposing hole HL has been formed, the outward movement of IPA is accelerated. Thus, the outer edge HLe of the exposing hole HL corresponding to the inner periphery of the ring-shaped liquid film widens to the outer perimeter of the upper surface of the substrate W, and all of the liquid film is discharged from the upper surface of the substrate W.

When forming the exposing hole HL, the fluid nozzle 45 is located at the central lower position which is above the substrate W, and discharges gas at the hole-forming flow rate. The gas that has been discharged from the central discharge port 45c forms a columnar or linear airflow running from the central discharge port 45c to the upper surface of the substrate W. The diameter of the same airflow increases as it retreats from the central discharge port 45c. When a large-diameter airflow collides with the liquid film while forming the exposing hole HL, IPA tends to remain inside the exposing hole HL. It is thus possible to narrow the airflow that collides with the liquid film on the substrate W, compared to when the exposing hole HL is formed by gas discharged from the central discharge port 45c of the fluid nozzle 45 located at the central upper position, thus helping to reduce the possibility of IPA remaining in the exposing hole HL when the exposing hole HL has been formed.

When widening the exposing hole HL, the fluid nozzle 45 is located at the central upper position which is above the central lower position, and discharges gas at the hole-widening flow rate which is greater than the hole-forming flow rate. However, when the gas is discharged at a high flow rate by the central discharge port 45c while the central discharge port 45c is located near the substrate W, the airflow other than the airflow that is parallel or substantially parallel to the upper surface of the substrate W often increases in volume or becomes stronger. Such airflow disturbance generates droplets that scatter toward the exposing hole HL, often interfering with outward movement of the IPA. It is therefore possible to reduce or weaken the disturbance of airflow, compared to when the gas is discharged at the hole-widening flow rate by the central discharge port 45c of the fluid nozzle 45 located at the central lower position.

According to the preferred embodiment, the fluid nozzle 45 is located at the central upper position not only during discharge of gas by the central discharge port 45c of the fluid nozzle 45 at the hole-widening flow rate, but also during increase of the flow rate of the gas discharged from the central discharge port 45c up to the hole-widening flow rate. It is thus possible to reduce or weaken disturbance of the airflow generated above the substrate W when the flow rate of the gas discharged from the central discharge port 45c is increased, thereby allowing the outer edge HLe of the exposing hole HL to smoothly approach the outer perimeter of the upper surface of the substrate W.

According to the preferred embodiment, the increase in the flow rate of gas per unit time is increased in a continuous or stepwise manner as time passes, when the flow rate of gas discharged from the central discharge port 45c of the fluid nozzle 45 located at the central upper position is increased up to the hole-widening flow rate. The rate at which the inner diameter of the ring-shaped liquid film of IPA is increased is approximately directly proportional to the flow rate of the gas discharged from the central discharge port 45c. This rate therefore increases as time passes. In other words, the inner periphery of the ring-shaped liquid film of IPA first widens slowly, and then widens rapidly. As a result, it is possible to shorten the time to remove the liquid film of IPA, while preventing the liquid film of IPA at the upper surface of the substrate W from dividing or while preventing generation of droplets from the liquid film of IPA that may scatter toward the exposing hole HL.

According to the preferred embodiment, the gas is discharged in a radial manner from the first annular discharge port 45a and second annular discharge port 45b that surround the rotational axis A1 of the substrate W, as an example of a vertical line passing through the central portion of the upper surface of the substrate W. This allows the upper surface of the substrate W to be covered by gas discharged from the first annular discharge port 45a and second annular discharge port 45b. Furthermore, the first annular discharge port 45a and second annular discharge port 45b initiate discharge of gas after, instead of before, the exposing hole HL is formed. The gas discharged from the first annular discharge port 45a and second annular discharge port 45b therefore does not interfere with formation of the exposing hole HL. After the exposing hole HL has been formed, the gas discharged from the first annular discharge port 45a and second annular discharge port 45b guides the gas discharged from the central discharge port 45c outward along the upper surface of the substrate W. The outer edge HLe of the exposing hole HL can thus be reliably brought near the outer perimeter of the upper surface of the substrate W.

According to the preferred embodiment, the substrate W is rotated while discharging gas at the drying flow rate, from the central discharge port 45c of the fluid nozzle 45 toward the central portion of the upper surface of the substrate W. Even if droplets of invisible size remain on the upper surface of the substrate W, the droplets evaporate while the substrate W is rotating. This allows the substrate W to be dried while protecting the upper surface of the substrate W by the gas discharged from the central discharge port 45c. The drying flow rate is higher than the hole-forming flow rate and lower than the hole-widening flow rate. At the central portion of the upper surface of the substrate W, a trace amount of IPA vapor is pressed against the substrate W by the gas discharged from the central discharge port 45c, and may remain there. Consequently, it is possible to reduce the amount of IPA vapor remaining at the central portion of the upper surface of the substrate W, compared to when the central discharge port 45c continuously discharges gas at the hole-widening flow rate, thus helping to prevent or alleviate reduction in quality of the substrate W caused by the vapor.

According to the preferred embodiment, not only is the substrate W rotated while discharging gas at the drying flow rate from the central discharge port 45c of the fluid nozzle 45 toward the central portion of the upper surface of the substrate W, but gas is also discharged in a radial manner from the first annular discharge port 45a and second annular discharge port 45b. It is therefore possible to protect the upper surface of the substrate W, not only by the gas discharged from the central discharge port 45c but also by the gas discharged from the first annular discharge port 45a and second annular discharge port 45b. The flow rate of gas discharged from the central discharge port 45c while the substrate W is being dried is lower than the flow rate of gas discharged from the first annular discharge port 45a and second annular discharge port 45b while the substrate W is being dried. This can decrease the amount of IPA vapor remaining at the central portion of the upper surface of the substrate W. On the other hand, in the region inside the upper surface of the substrate W other than the central portion of the upper surface of the substrate W, the gas discharged from the first annular discharge port 45a and second annular discharge port 45b causes outward acceleration of the gas discharged from the central discharge port 45c along the upper surface of the substrate W. This helps promote drying of the substrate W.

According to the preferred embodiment, heating of the substrate W causes evaporation of IPA at the interface between the liquid film of IPA and the upper surface of the substrate W. A vapor layer VL containing IPA is thereby formed between the liquid film of IPA and the upper surface of the substrate W. All or a portion of the liquid film of IPA is supported on the upper surface of the substrate W via the vapor layer VL of IPA, thus rising up from the upper surface of the substrate W. An exposing hole HL is formed in this state, with the outer edge HLe of the exposing hole HL widening up to the outer perimeter of the upper surface of the substrate W. Since the substrate W is being heated, then if droplets remain in the exposing hole HL when the exposing hole HL has been formed, or if droplets scattered from the liquid film during widening of the exposing hole HL enter into the exposing hole HL, those droplets will immediately evaporate. By eliminating or reducing such droplets, it is possible to lower the probability of blemishes such as watermarks forming in the upper surface of the substrate W, or of the pattern PA collapsing at the upper surface of the substrate W.

Next, other preferred embodiments will be described.

If the fluid nozzle 45 can move vertically parallel above the substrate W being held by the spin chuck 10, then it is not necessary for the fluid nozzle 45 to be able to move horizontally.

It is not necessary for either or both the solvent nozzle 45D and first gas nozzle 45C of the fluid nozzle 45 to be held by the second gas nozzle 45A of the fluid nozzle 45. In this case, a special nozzle actuator for the solvent nozzle 45D may be provided, so long as the solvent nozzle 45D is a scan nozzle. The same applies to the first gas nozzle 45C.

The flow rate of gas discharged from the central discharge port 45c of the fluid nozzle 45 may be increased to the hole-widening flow rate while moving the fluid nozzle 45 to the central lower position, so long as this is not done immediately after the exposing hole HL has been formed, i.e., so long as it is done after the exposing hole HL has reached a certain size. The fluid nozzle 45 may then be raised to the central upper position while discharging gas to the central discharge port 45c at the hole-widening flow rate.

The first annular discharge port 45a of the fluid nozzle 45 may also be caused to initiate discharge of gas before forming the exposing hole HL. The same applies to the second annular discharge port 45b of the fluid nozzle 45. The flow rate of gas discharged from either or both the first annular discharge port 45a and second annular discharge port 45b may be equal to or less than the maximum value for the flow rate of the gas discharged from the central discharge port 45c. During the period from formation of the exposing hole HL until the substrate W is dried by spin drying, the first annular discharge port 45a and second annular discharge port 45b may be caused to halt discharge of gas.

The liquid film of IPA may be discharged from the upper surface of the substrate W by widening the exposing hole HL, not with the liquid film of IPA lifted up from the upper surface of the substrate W but rather with the liquid film in contact with the upper surface of the substrate W. In this case, the hot plate 61 may be omitted.

The substrate processing apparatus 1 is not limited to an apparatus to process a disc-shaped substrate W, and may be an apparatus to process a polygonal substrate W.

Two or more arrangements among all the arrangements described above may be combined. Two or more steps among all the steps described above may be combined.

The preferred embodiments of the present invention are described in detail above, however, these are just detailed examples used for clarifying the technical contents of the present invention, and the present invention should not be limitedly interpreted to these detailed examples, and the spirit and scope of the present invention should be limited only by the claims appended hereto.

This application claims the benefit of priority to Japanese Patent Application No. 2024-004005 filed on Jan. 15, 2024. The entire contents of this application are hereby incorporated herein by reference.

1. A substrate processing method comprising:
discharging processing liquid toward an upper surface of a substrate held horizontally to cover an entire upper surface of the substrate with a liquid film which is a film of the processing liquid,
discharging gas at a hole-forming flow rate from a central discharge port of a fluid nozzle located at a central lower position which is a position above the substrate, toward a central portion of the upper surface of the substrate to form at a central portion of the liquid film an exposing hole where the central portion of the upper surface of the substrate is exposed, and
discharging gas at a hole-widening flow rate which is greater than the hole-forming flow rate, from the central discharge port of the fluid nozzle located at a central upper position which is a position higher than the central lower position, toward the central portion of the upper surface of the substrate to widen an outer edge of the exposing hole up to an outer perimeter of the upper surface of the substrate.

2. The substrate processing method according to claim 1, wherein discharging the gas at the hole-widening flow rate includes increasing a flow rate of the gas discharged from the central discharge port up to the hole-widening flow rate, when the fluid nozzle is located at the central upper position.

3. The substrate processing method according to claim 2, wherein discharging the gas at the hole-widening flow rate includes increasing the flow rate of the gas discharged from the central discharge port up to the hole-widening flow rate while increasing an increase in the flow rate of the gas per unit time as time passes, when the fluid nozzle is located at the central upper position.

4. The substrate processing method according to claim 1, further including covering the upper surface of the substrate with gas that has been discharged in a radial manner from an annular discharge port surrounding a vertical line passing through the central portion of the upper surface of the substrate, after the exposing hole has been formed.

5. The substrate processing method according to claim 1, further including rotating the substrate around a vertical rotational axis passing through the central portion of the upper surface of the substrate while causing the central discharge port to discharge gas toward the central portion of the upper surface of the substrate at a drying flow rate which is higher than the hole-forming flow rate and lower than the hole-widening flow rate, after the outer edge of the exposing hole has been widened up to the outer perimeter of the upper surface of the substrate.

6. The substrate processing method according to claim 5, further including covering the upper surface of the substrate with gas that has been discharged at a flow rate in a radial manner from an annular discharge port surrounding a vertical line passing through the central portion of the upper surface of the substrate, while rotating the substrate around the vertical rotational axis and causing the central discharge port to discharge the gas toward the central portion of the upper surface of the substrate at the drying flow rate after the outer edge of the exposing hole has been widened up to the outer perimeter of the upper surface of the substrate, and
the drying flow rate is lower than the flow rate.

7. The substrate processing method according to claim 1, further including forming between the liquid film and the upper surface of the substrate a vapor layer of the processing liquid that raises the liquid film from the upper surface of the substrate by heating the substrate before the exposing hole is formed.

8. A substrate processing apparatus comprising:
a substrate holder that holds a substrate horizontally,
a processing liquid nozzle that discharges processing liquid toward an upper surface of the substrate held by the substrate holder to cover an entire upper surface of the substrate with a liquid film which is a film of the processing liquid,
a fluid nozzle that discharges gas at a hole-forming flow rate from a central discharge port toward a central portion of the upper surface of the substrate held by the substrate holder, while being located at a central lower position which is a position above the substrate to form at a central portion of the liquid film an exposing hole where the central portion of the upper surface of the substrate is exposed,
a nozzle actuator that lifts the fluid nozzle from the central lower position to a central upper position, and
a flow rate adjustment valve that changes a flow rate of gas discharged from the central discharge port of the fluid nozzle to cause the central discharge port to discharge gas toward the central portion of the upper surface of the substrate held by the substrate holder at a hole-widening flow rate which is greater than the hole-forming flow rate and to widen an outer edge of the exposing hole up to an outer perimeter of the upper surface of the substrate when the fluid nozzle is located at the central upper position.
